(19) United States
(12) Patent Application Publication
(10) Pub. No.: US 2007/0126445 A1
(43) Pub. Date: Jun. 7, 2007

(54) Integrated circuit package testing devices and methods of making and using same

(75) Inventors: Amos Jay Stutzman, Boise, ID (US); Daniel P. Cram, Boise, ID (US)

Correspondence Address: DICKSTEIN SHAPIRO LLP, 1825 EYE STREET NW, Washington, DC, 20006-5403, US

(73) Assignee: MICRON TECHNOLOGY, INC.

(21) Appl. No.: 11/289,467

(22) Filed: Nov. 30, 2005

(51) Int. Cl. G01R 31/02

(52) U.S. Cl. 324/755

(57) ABSTRACT

Integrated circuit package testing devices having a substrate with a cavity, and a device connecting a latch to said substrate, wherein said latch provides an unobstructed path to a center of the cavity, and the method for making and using the devices.

### FIELD OF THE INVENTION

The present invention relates generally to integrated circuit package testing devices and the methods of making and using such devices.

### BACKGROUND OF THE INVENTION

Integrated circuit (IC) packages, such as charge-coupled-devices (CCD) and complementary metal oxide semiconductor (CMOS) image sensors, are typically tested after their manufacture. The integrated circuits are temporarily installed on a circuit board, tested, and then removed from the circuit board and shipped. Accordingly, test sockets are typically used to install the IC packages on the printed circuit board for testing. These test sockets include multiple contacts to connect each of the terminals of the IC package to corresponding conductors on the printed circuit board. Since the test sockets are used repeatedly in high volume IC package manufacture, it is desirable that the sockets be durable and capable of reliable, repeated operation.

One example of an IC package is a “flip-chip package,” wherein discrete conductive elements, such as solder balls, are attached directly to or formed on the bond pads at the ends of electrical traces formed on the active surface of a semiconductor die. The die is then “flipped,” or mounted face down, so that the solder balls may connect with contact members of another device, such as terminal pads of a carrier substrate.

Another example is a “chip scale package,” which includes a die along with one or more package elements such as encapsulating material in the form of thin protective coatings formed of a dielectric material bonded to the active surface, sides and back side of the semiconductor die. In addition, solder balls may be attached to or formed on ends of electrical traces on the active surface of the semiconductor die or directly to the semiconductor die's bond pads through openings in the encapsulating material.

A “Ball Grid Array” (BGA) serves as yet another example that involves even more packaging. The semiconductor die is wire bonded to terminal pads on the top side of an interposer substrate and encapsulated thereon. Solder balls are bonded to electrical traces on the bottom side of the substrate that are electrically connected to the terminal pads.

The above-described packages are only a few examples of the many types of IC packages that are currently being manufactured. Other examples of IC packages include quad flat no lead (QFN) IC packages, micro lead frame (MLF) IC packages, leaded chip carrier (LCC) IC packages, quad flat pack (QFP) IC packages, and thin small outline packages (TSOP). As described above, the IC packages could have different thicknesses depending upon the application of the package. Accordingly it is desirable to construct IC package testing devices that are capable of readily accommodating IC packages of varied thicknesses. It is also desirable to construct IC package testing devices that are capable of testing a variety of IC packages, including, but not limited to, IC packages having image sensors contained therein.

### BRIEF SUMMARY OF THE INVENTION

The invention provides an IC package testing device capable of accommodating IC packages of varied thicknesses. Exemplary embodiments of the invention relate to integrated circuit package testing devices having a substrate with a cavity, and a device connecting a latch to said substrate, wherein said latch provides an unobstructed path to a center of the cavity, and the method for making and using the devices.

### BRIEF DESCRIPTION OF THE DRAWINGS

The above-described features and advantages of the invention will be more clearly understood from the following detailed description, which is provided with reference to the accompanying drawings in which:

FIG. 1 illustrates an exploded view of an IC package testing device constructed in accordance with one exemplary embodiment of the invention;

FIG. 2 illustrates an angled view of an assembled FIG. 1 IC package testing device;

FIGS. 3A, 3B, 3C, and 3D illustrate profile, side, bottom-up, and top-down views, respectively, of the FIG. 2 assembled IC package testing device;

FIG. 4 illustrates a top-down view of the FIG. 2 IC package testing device coupled to a printed circuit board;

FIGS. 5A and 5B illustrate cross-sectional views of the FIG. 2 IC package testing device along line 5-5;

FIG. 6 illustrates an angled bottom view of the FIG. 2 IC package testing device; and

FIG. 7 is a diagram of a processor system incorporating the FIG. 2 IC package testing device.

### DETAILED DESCRIPTION OF THE INVENTION

In the following detailed description, reference is made to the accompanying drawings, which form a part hereof and show by way of illustration specific embodiments in which the invention may be practiced. These embodiments are described in sufficient detail to enable those skilled in the art to practice the invention, and it is to be understood that other embodiments may be utilized, and that structural, logical, and electrical changes may be made without departing from the spirit and scope of the present invention. The progression of processing steps described is exemplary of embodiments of the invention; however, the sequence of steps is not limited to that set forth herein and may be changed as is known in the art, with the exception of steps necessarily occurring in a certain order.

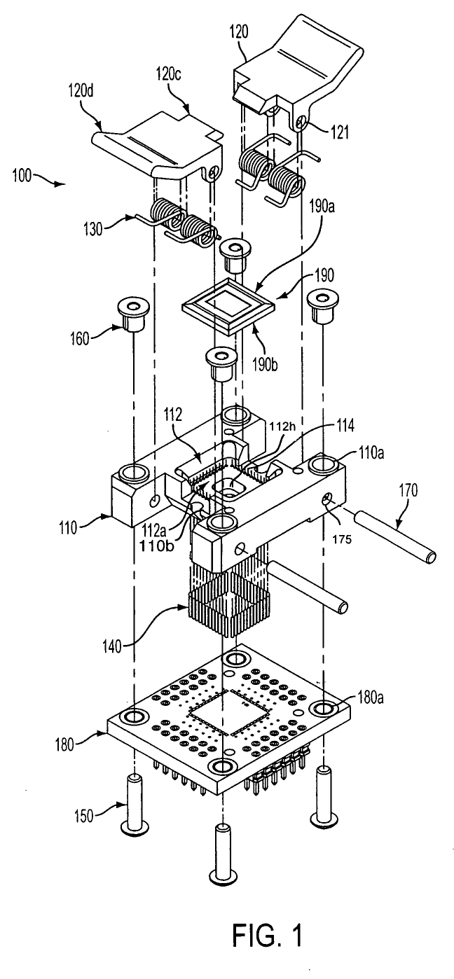

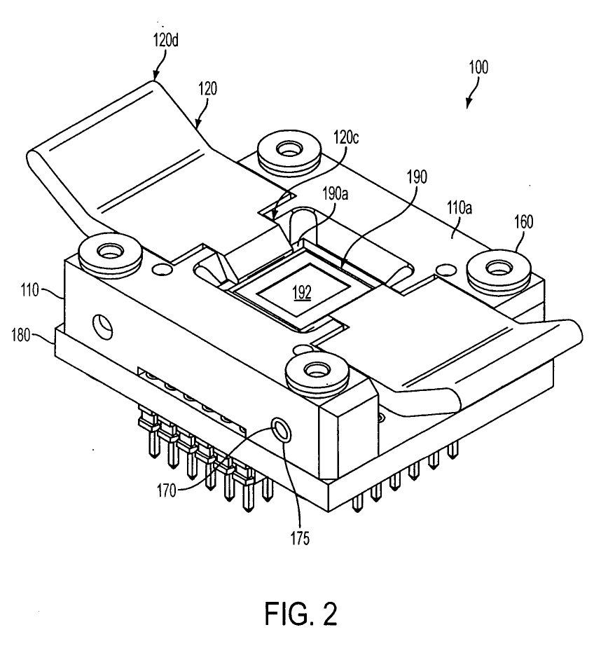

Referring now to the figures, where like reference numbers designate like elements, FIG. 1 illustrates an embodiment of an integrated circuit (IC) package testing device 100 constructed in accordance with an embodiment of the invention. Specifically, FIG. 1 illustrates an exploded view of an IC package testing device 100 capable of accommodating IC packages (e.g., IC package 190) of various thickness while allowing an unobstructed path to the center of the IC package, and maintaining a low profile, as discussed below with respect to FIGS. 2-5.

The FIG. 1 IC package testing device 100 includes a substrate or socket base 110 that could be formed of any non-conductive material. The socket base 110 is formed having a cavity 112 within which an IC package 190 is inserted and tested. The IC package 190 is inserted into the cavity 112 such that the conductive pads of the IC package 190 contact a plurality of conductive lines 140, which have conductive pads 114 provided on a periphery (relative to the center) of the cavity 112. The conductive pads of the IC package 190 must be on a surface 190b of the IC package 190 that is seated on the device seating plane 112a of the cavity 112 to ensure an electrical connection. The conductive pads 114 of the conductive lines 140 are coupled to additional (e.g., readout) circuitry (not shown) through an optional interposer card 180.

The socket base 110 and the interposer card 180 are optionally coupled together by mounting screws 150 and threaded inserts 160, which are inserted into mounting holes 180a, 110a formed in the interposer card 180 and socket base 110, respectively. Although the socket base 110 and the interposer card 180 are illustrated as being coupled by a mounting screw 150 and threaded inserts 160, it is not intended to be limiting. For example, the socket base 110 and the interposer card 180 could be coupled together by any fastener, including, but not limited to, screws, bolts, or adhesive glue.

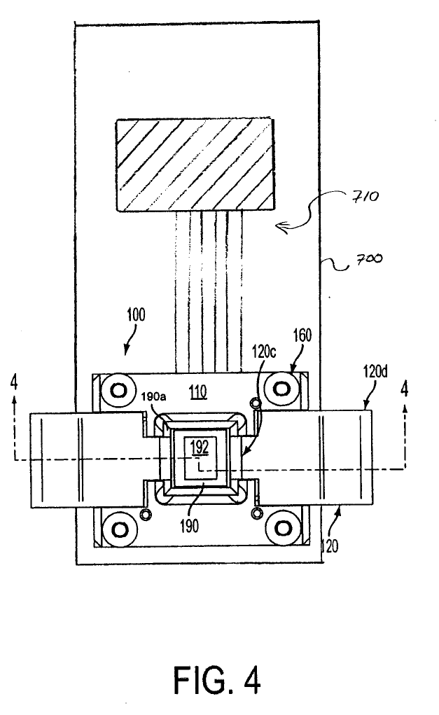

The interposer card 180 may optionally be soldered to a printed circuit board 700 (FIG. 4), which in turn may be coupled to external circuitry 710 (FIG. 4) that is capable of generating and displaying an image. The interposer card 180 provides a simplified mechanism for coupling the socket base 110 to external circuitry 710 (FIG. 4) as compared to coupling the conductive lines 140 directly to external circuitry 710 (FIG. 4). Coupling the conductive lines 140 directly to external circuitry 710 (FIG. 4) is possible, however, and the illustrated exemplary embodiment is not intended to limit the invention to use with an interposer card 180.

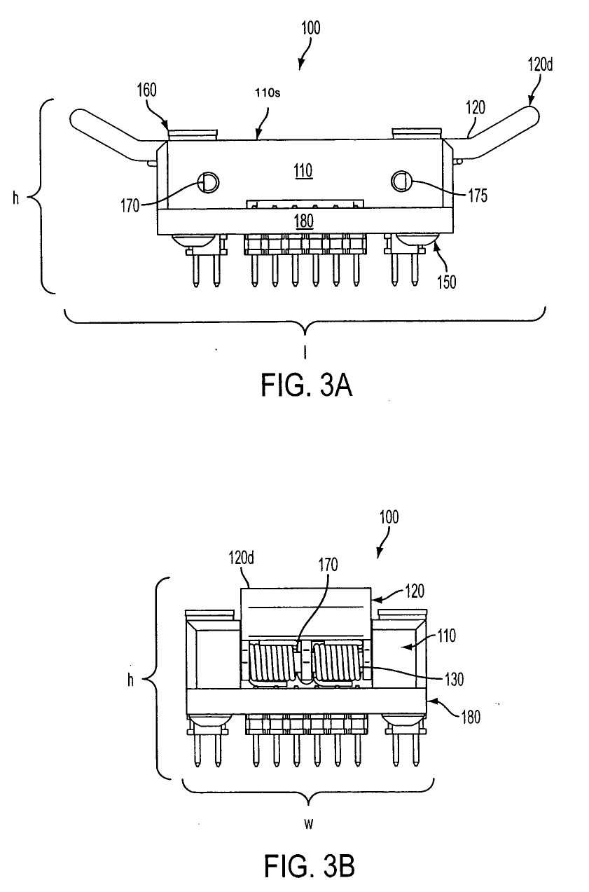

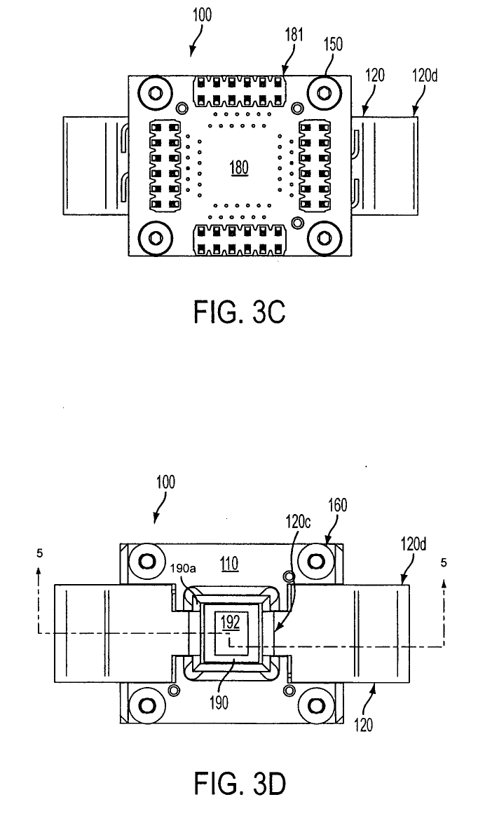

The IC package testing device 100 also includes pivot pins 170, which are connected to the socket base 110 by pivot pin holes 175 provided in the socket base 110. The illustrated pivot pin holes 175 are provided such that two pivot pin holes 175 are axially aligned on each side of the socket base 110. The pivot pin 170 is inserted through each of the two axially aligned pivot pin holes 175 provided in the socket base 110. The pivot pin 170 is also inserted through each of three axially aligned pivot pin holes 121, as further discussed with respect to FIG. 3B, provided in each latch 120 on each side of the socket base 110, and through coils of two torsion springs 130.

The torsion spring 130 provides a normal force pressure on the latch 120 such that a device clip portion 120c of the latch 120 has a normal force pressure on the device seating plane 112a of the cavity 112 in the socket base 110 when the IC package 190 is inserted. When the IC package is 190 is not inserted, the device clip portion 120c does not contact the device seating plane 112a of the cavity 112; instead, the device clip portion 120c rests on a lip 110b of the socket base 110. The lip 110b of the socket base 110 prevents possible damage to the device clip portion 120c of the latch 120 by preventing contact with the device seating plane 112a of the cavity 112.

FIG. 1 illustrates each latch 120 having a distal portion 120d on which a distal force pressure can be applied to counter the normal force pressure on the device clip portion 120c of the latch 120. The distal force pressure lifts the device clip portion 120c away from the socket base 110, which allows for the insertion of an IC package, e.g., IC package 190, into the cavity 112 of the socket base 110. The device clip portion 120c secures edges of an IC package, e.g., IC package 190 having an edge 190a, as discussed further with respect to FIGS. 2-5B.

Although illustrated as having two springs 130, the FIG. 1 embodiment of the IC package testing device 100 is not intended to be limiting in any way. For example, the IC package testing device 100 could comprise only one spring 130 or more than two springs 130. Accordingly, the latch 120 could have more or less pivot pin holes 121, depending on the intended application and depending on the number of springs used. It should also be noted that the socket base 110 could have more or less than two axially aligned pivot pin holes 175.

It should also be noted that the FIG. 1 springs 130 are only exemplary devices that apply a normal force pressure on the latches 120 such that the device clip portion 120c of the latch 120 has a normal force pressure towards the device seating plane 112a of the cavity 112, and are not limiting in any way. For example, any device that can apply a normal pressure force on the latch 120 such that the device clip portion 120c of the latch 120 has a normal force pressure towards the device seating plane 112a of the cavity 112 can be used, including, but not limited to, pneumatic cylinders and linear actuators.

It should be noted that although the FIG. 1 embodiment illustrates the IC package testing device 100 as having two latches 120, it is not intended to be limiting in any way. For example, the IC package testing device 100 could have less than or more than two latches 120. It should also be noted that the latches 120 could be placed anywhere on the socket base 110, and are not limited to being located perpendicular or parallel to a side of the socket base 110. For example, the latches 120 could secure the IC package 190 being tested by the comers of the IC package 190.

It should also be noted that the IC package 190 could be, without being limiting, packaged as a chip scale package, ball grid array, flip-chip package, quad flat no lead (QFN) packages, micro lead frame (MLF) packages, leaded chip carrier (LCC) packages, quad flat pack (QFP) packages, and thin small outline packages (TSOP). If the IC package 190 is packaged as a flip-chip, TSOP, QFP, LCC, QFN, or MLF package that includes an image sensor, a hole 112h could be formed through the socket base 110 localized at a center of the cavity 112, and a light source could be placed below the socket base for testing, as discussed below with respect to FIG. 2.

FIG. 2 illustrates an angled view of an assembled FIG. 1 IC package testing device 100 with an IC package 190 inserted therein. The IC package testing device 100 is illustrated in a closed position whereby two edges 190a of the IC package 190 are respectively secured by the device clip portions 120c of each latch 120 on sides of the socket base 110 that are opposite one another. Although the latches 120 are illustrated as being opposite each other and having a pivot axis parallel to one another, it is not intended to be limiting in any way. For example, the latches 120 could be on two adjacent sides of the socket base 110 having a pivot axis perpendicular to one another, if desired, or four latches 120 could be provided on all four sides of socket base 110.

The FIG. 2 latches 120 pivot about an axis provided by the pivot pins 170. The pivot pins 170 are inserted into the pivot pin holes 175 provided in the socket base 110. The latches 120 are secured to the pivot pins 170 by the pivot pin holes 121 (FIG. 1) provided on the latches 120, as discussed above with respect to FIG. 1. As illustrated in FIG. 2, the latches 120 are provided such that there is an unobstructed path to a center 192 of the IC package 190 being tested. By providing an unobstructed path to the center 192 of the IC package 190 being tested, the IC package 190 can be readily inserted and removed into and out of the cavity of the IC package testing device 100.

An unobstructed path to the center 192 of the IC package 190 being tested also allows for the testing of image sensors. For example, image sensors, such as CMOS and CCD image sensors, typically include an array of pixel cells containing photosensors, wherein each pixel cell produces a signal corresponding to the intensity of light impinging on that pixel cell when an image is focused on the array. Like most IC packages, image sensors are typically tested to ensure that the image sensors work properly, i.e., that there is a minimum number of malfunctioning pixel cells in the array of pixel cells. Image sensors are typically tested by exposing the array of pixel cells to an image, capturing the signals produced by the array of pixel cells, and subsequently processing the signals to display an image.

In displaying an acquired image, a display structure, for example, a computer screen, will display a complete image only if the complete image is captured by the array of pixel cells. For example, if the array of pixel cells were subjected to white light from a light source, the expected display image would be an all white image. If, on the other hand, the image appears to have a nearly completely white image with several “holes” or defects created by the failure to capture the complete image (in this case, a white light) from the array of pixel cells, the array of pixel cells has one or more non-functional pixel cells. The pixel cell array may also be exposed to no light and read for defects.

Image sensors having non-functional pixel cells will likely be segregated into groups by the manufacturer, depending on the number of non-functional pixels each image sensor contains. The image sensors can be salvaged and used for various applications, or, if necessary, can be discarded completely. For example, image sensors having non-functional pixels could be used in applications that do not require the highest resolution, and would likely not be used in high-end applications such as, for example, professional photography equipment. Alternatively, the image sensors could be discarded altogether if the image sensors contain a significant number of non-functional pixels.

The FIG. 2 IC package testing device 100 provides an unobstructed path to the center 192 of the IC package 190 being tested, which allows light to impinge on the center 192 of the IC package 190; therefore, the IC package testing device 100 can be used for the testing of various types of IC packages, including, but not limited to, image sensors. The IC package testing device 100 also provides latches 120 that allow a user to readily insert and remove IC packages (e.g., IC package 190), which provides for a high throughput potential, i.e., testing a high volume of IC packages.

The unobstructed path to the center 192 of the IC package 190 being tested also, more broadly, allows for unimpeded physical access to the IC package 190 for various purposes, including, but not limited to, micro-probing the circuitry and thermal imaging of the IC package being tested (e.g., IC package 190).

FIGS. 3A, 3B, 3C, and 3D illustrate profile, side, bottom-up, and top-down views, respectively, of the FIG. 2 assembled IC package testing device 100. As illustrated in FIG. 3A, the IC package testing device 100 has a low profile, i.e., a height (h) of less than one inch. The latches 120 are illustrated in a closed position, whereby a substantial portion of the latches 120 (except for the distal portions 120d) are planar to a top surface 110s of the socket base 110. The distal portions 120d of the latches 120 in the closed position remain to a side relative to the socket base 110 thereby allowing an unobstructed path to the IC package, e.g., IC package 190, as discussed above with respect to FIG. 2. Additionally, the distal portion 120d of the latch is slightly bent in a direction towards the normal force pressure applied by the spring 130 (FIG. 2). The slight bend of the distal portion 120d allows for leverage when opening the latches 120 in operation of the IC package testing device 100.

The low profile of the IC package testing device 100 may also prevent “shadowing effects” during the testing of image sensors. As discussed above with respect to FIG. 2, an unobstructed path to the center 192 of the IC package 190 being tested is advantageous for testing IC packages with an array of pixel cells contained therein.

High profile latches (i.e., latches that are not to a side of the device seating plane 112a (FIG. 1) of the IC package testing device 100), on the other hand, may interfere with light directed to the center of the IC package being tested. The interference of light may further result in incomplete capture of the image impinging on the array of pixel cells. The obstruction caused by high profile latches may result in “holes” in the captured image, resulting in fully functional IC packages being segregated into groups of non-functional IC packages, resulting in lower yield and increased overall costs of production. The FIG. 3A IC package testing device 100 mitigates any “shadowing effect.”

Although the IC package testing device 100 has been described as having a height (h) of less than one inch, the description is not intended to be limiting in any way. For example, for larger IC packages, the IC package testing device 100 may have a height (h) equal to or more than one inch, or less than one inch. Even if the height (h) of the IC package testing device 100 is greater than one inch, the “shadowing effect” is prevented because the latches 120 are positioned to a side of the IC package testing device 100.

The FIG. 3A embodiment of the IC package testing device 100 is illustrated as having a length (l) of less than 2 inches. It should be noted, however, that the illustrated length is not intended to be limiting in any way. For example, the length of the IC package testing device 100 could be longer or shorter or shorter than 2 inches, depending on the intended application.

FIG. 3B illustrates a head-on view of the IC package testing device 100. As illustrated, the pivot pin 170 is inserted through the springs 130 and through the pivot pin holes 121 (FIG. 1) of each latch 120. The latches 120 are illustrated in the closed position, wherein a majority of the latch 120 (except for the distal portion 120d) is substantially planar to the socket base 110. The illustrated IC package testing device 100 has a height (h) and a width (w). The width (w) of the illustrated IC package testing device 100 is less than an inch. It should be noted, however, that the illustrated width (w) is not intended to be limiting in any way. For example, the width (w) of the IC package testing device 100 could be greater than or equal to an inch, depending on the intended application.

FIG. 3C illustrates a bottom-up view of the IC package testing device 100. The distal portions 120d of the latches 120 illustrated in a closed position are to a side of the socket base 110. The interposer card 180 is illustrated as having electrical circuitry 181 that provide an electrical connection from the conductive lines 140 (FIG. 1) to external circuitry 710 (FIG. 4). For example, the electrical circuitry 181 of the interposer card 180 could be soldered onto a printed circuit board 700 (FIG. 4), which, in turn, is electrically coupled to external circuitry 710 (FIG. 4).

FIG. 3C also illustrates the mounting screws 150 that couple the interposer card 180 with the socket base 110 (FIG. 3B). It should be noted that the mounting screws 150 are optional, and are not intended to be limiting in any way.

FIG. 3D illustrates a top-down view of the IC package testing device 100 having an IC package 190 inserted therein. The top-down view illustrates the unobstructed path to the center 192 of the IC package 190 being tested. As illustrated, the device clip portion 120c of the latches 120 correspond to an edge 190a of the IC package 190 being tested. The device clip portions 120c secure the IC package 190 within the cavity 112 (FIG. 2) of the socket base 110, and provide a normal force pressure on IC package 190 such that proper electrical connections between the conductive pads (not shown) of the IC package 190 and the conductive pads 114 (FIG. 1) on the device seating plane 112a (FIG. 1) are maintained during testing.

FIG. 4 illustrates a top-down view of the IC package testing device 100 coupled to a printed circuit board 700, which includes external circuitry 710. The external circuitry 710 can readout signals originating from the IC package 190 tested by the IC package testing device 100.

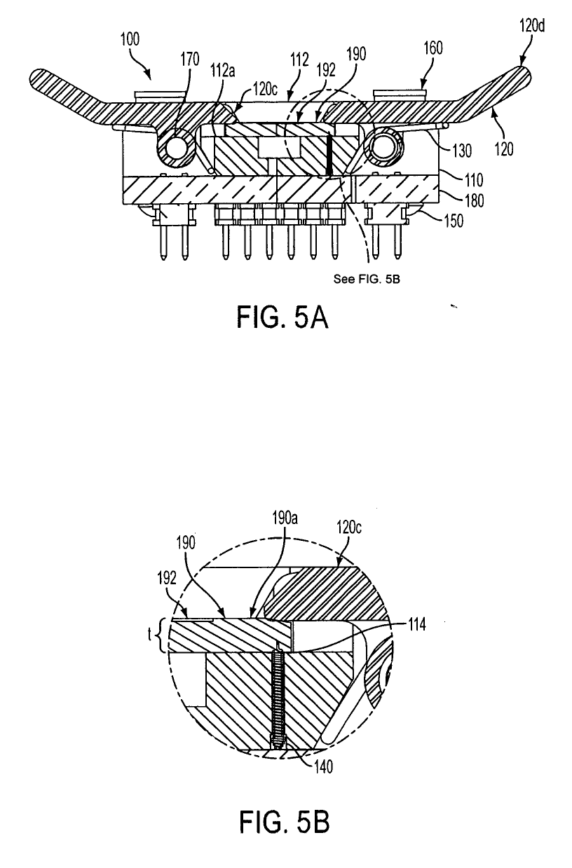

FIGS. 5A and 5B illustrate cross-sectional views of the FIG. 2 IC package testing device 100, and the IC package 190 inserted therein, taken along the line 5-5 of FIG. 3D. The FIG. 5A cross-sectional view illustrates the IC package 190 seated on the device seating plane 112a of the cavity 112. The device clip portions 120c of the latches 120 apply a normal force pressure on the edge 190a of the IC package 190 such that conductive pads of the IC package 190 are properly coupled to the conductive pads 114 (FIG. 5B) provided on the periphery of the cavity 112. The conductive pads 114 of the conductive lines 140 are coupled to external circuitry 710 (FIG. 4) through an optional interposer card 180.

FIG. 5A also illustrates the mounting screws 150 and the threaded inserts 160 that couple the socket base 110 and the interposer card 180. Additionally, the latches 120 secure the IC package 190 such that there is an unobstructed path to the center 192 of the IC package, as discussed above with respect to FIG. 2. The latches 120 that are coupled to the socket base 110 by pivot pins 170. The springs 130 provide a normal force pressure against the latches 120 such that the device clip portion 120c of the latch applies a force against the edges 190a of the IC package 190.

One of the advantages of the IC package testing device 100 is that the latches 120 are capable of pivoting about an axis provided by the pivot pins 170; therefore, the latches 120 can accommodate IC packages (e.g., IC package 190) having various thicknesses. For example, as illustrated in FIG. 4B, an IC package that has a thickness greater than the thickness (t) of IC package 190 can be accommodated because the latches 120 are able to pivot about an axis provided by the pivot pins 170. The capability of the IC package testing device 100 to accommodate IC packages of various thicknesses allows for efficient testing of a multitude of IC packages manufactured. Efficient testing of IC packages reduces the costs associated with testing a first IC package of a first thickness using a first IC package testing device, and testing a second IC package of a second thickness that is different from the first thickness using a second IC package testing device.

Another advantage of the capability of the latches 120 to pivot about an axis provided by the pivot pins 170, is that the IC package testing device 100 is capable of securing IC packages 190 having non-uniform surfaces and non-uniform thicknesses. For example, an IC package having non-uniform surfaces would be secured to the socket base 110 by the device clip portion 120c of the latch 120 contacting an uppermost surface of the non-uniform IC package being tested.

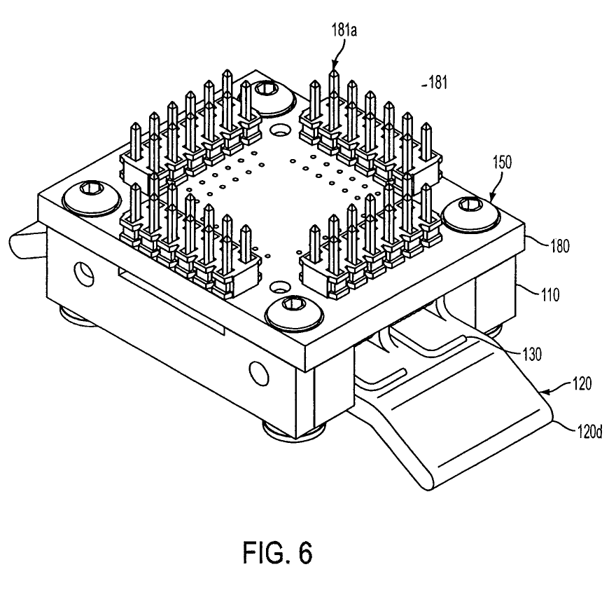

FIG. 6 illustrates an angled bottom view of the FIG. 2 IC package testing device 100. The interposer card 180 has electrical circuitry 181 that couples the socket base 110 with external circuitry 710 (FIG. 4). The external circuitry 181 is illustrated as comprising twelve prongs 181a on each side of the interposer card 180. The prongs 181a can be readily inserted into and removed from corresponding mating pin receptacles in a printed circuit board during testing of the IC package 190 (FIG. 2). It should be noted, however, that the prongs 181a could be solder terminals of board-to-board connectors, which are inserted into holes and soldered on a corresponding printed circuit board.

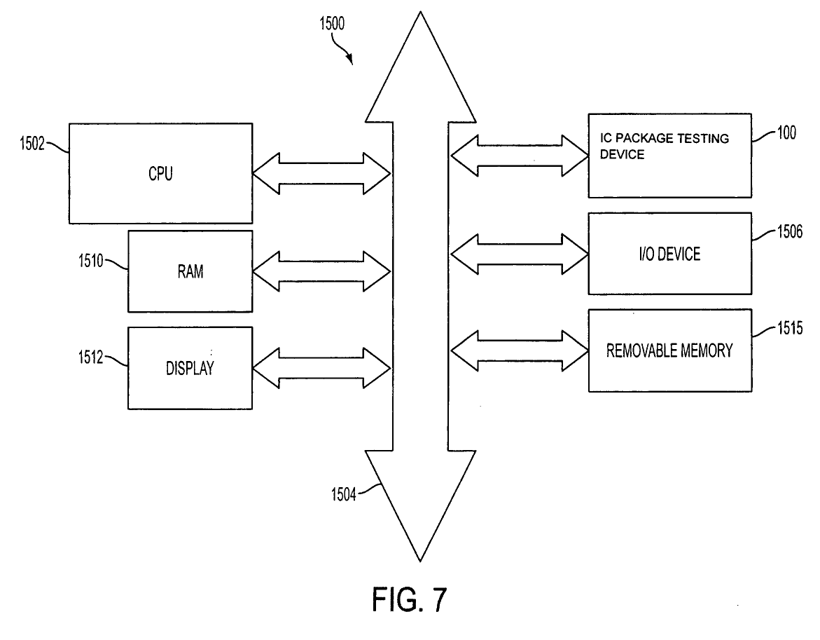

FIG. 7 illustrates a processor-based system 1500 that may be used to test the IC package 190 (e.g., FIG. 2) in conjunction with an exemplary IC package testing device 100 of the invention. The processor-based system 1500 could be programmed to operate the illustrated IC package testing device 100 and could be used to determine whether any defects are present in the IC package 190 (FIG. 2). The device 100 includes the IC package 190 being tested. The IC package 190 (FIG. 2) could be intended to be inserted into a computer system, camera system, scanner, machine vision, vehicle navigation, video phone, surveillance system, auto focus system, star tracker system, motion detection system, image stabilization system, medical device, or other image capture and processing system.

The processor-based system 1500 generally comprises a central processing unit (CPU) 1502, such as a microprocessor, that communicates with an input/output (I/O) device 1506 over a bus 1504. The IC package testing device 100 also communicates with the CPU 1502 over the bus 1504. The processor-based system 1500 also includes random access memory (RAM) 1510, and can include removable memory 1515, such as flash memory, which also communicates with CPU 1502 over the bus 1504. If the IC package 190 (FIG. 2) tested includes an image sensor, a display 1512 can optionally be included to display the image being captured by the image sensor of the IC package 190 (FIG. 2).

The above description and drawings illustrate exemplary embodiments which achieve the objects, features, and advantages of the present invention. Although certain advantages and exemplary embodiments have been described above, those skilled in the art will recognize that substitutions, additions, deletions, modifications, and/or other changes may be made without departing from the spirit or scope of the invention. Accordingly, the invention is not limited by the foregoing description but is only limited by the scope of the appended claims.

What is claimed as new and desired to be protected by Letters Patent of the United States is:

1. An integrated circuit package testing device, comprising:
a socket base having at least one cavity;
at least one latch; and
at least one device connecting said at least one latch to said socket base, said latch capable of pivoting about an axis and providing an unobstructed path to a center of said cavity.

2. The integrated circuit package testing device of claim 1, wherein said at least one device is a torsion spring.

3. The integrated circuit package testing device of claim 2, wherein said at least one spring is connected to said socket base by a pivot pin that is inserted into at least one hole in said socket base.

4. The integrated circuit package testing device of claim 2, wherein said socket base has a plurality of conductive lines, each conductive line further comprising a conductive pad located within said cavity.

5. The integrated circuit package testing device of claim 4, wherein said plurality of conductive lines are electrically coupled to an interposer card.

6. The integrated circuit package testing device of claim 5, wherein said socket base is mounted on said interposer card.

7. The integrated circuit package testing device of claim 5, wherein said interposer card is further soldered to a printed circuit board.

8. The integrated circuit package testing device of claim 5, wherein said interposer card and said socket base are coupled together.

9. The integrated circuit package testing device of claim 8, wherein said interposer card and said socket base are coupled together by a fastener.

10. The integrated circuit package testing device of claim 1, wherein a portion of said latch applies a force pressure on a periphery of said cavity.

11. The integrated circuit package testing device of claim 1, wherein a height of said integrated circuit package testing device is less than approximately one inch.

12. The integrated circuit package testing device of claim 1, wherein a length of said integrated circuit package testing device is less than approximately two inches as measured in a direction perpendicular to said path to said center of said cavity and perpendicular to a direction of said pivot axis.

13. The integrated circuit package testing device of claim 1, wherein said device maintains a force pressure on said latch such that said latch impinges on a surface of said cavity in said socket base.

14. The integrated circuit package testing device of claim 1, further comprising a second device connecting a second latch to said socket base, said second latch capable of pivoting about an axis and providing an unobstructed path to said center of said cavity.

15. The integrated circuit package testing device of claim 14, wherein said pivot axis of said second latch is parallel to said pivot axis of said at least one latch.

16. The integrated circuit package testing device of claim 14, wherein said second latch and said at least one latch are on opposite sides of said cavity.

17. The integrated circuit package testing device of claim 1, wherein said at least one device is a pneumatic cylinder.

18. The integrated circuit package testing device of claim 1, wherein said at least one device is a linear actuator.

19. A method of forming an integrated circuit package testing device, comprising:
forming a socket base having at least one cavity;
forming at least one latch; and
coupling said at least one latch to said socket base by a spring, said at least one latch providing an unobstructed path to a center of said cavity.

20. The method of claim 19, further comprising the step of inserting a pivot pin into holes in said substrate, through coils in said spring, and through holes in said latch.

21. The method of claim 19, further comprising forming said socket base with a plurality of conductive pads within said cavity.

22. The method of claim 21, further comprising forming said socket base with a plurality of conductive lines.

23. The method of claim 19, further comprising coupling said socket base with an interposer card.

24. The method of claim 23, further comprising the act of mounting said interposer card onto a printed circuit board.

25. A test system, comprising:
a processor;
an integrated circuit package testing device, comprising;
a socket base having at least one cavity,
first and second latches, and
first and second springs respectively connecting said first and second latches to said socket base, said latches capable of pivoting about a respective axis and providing an unobstructed path to a center of said cavity, and
readout circuitry.

26. The test system of claim 25, wherein said first and second springs are connected to said socket base by respective pivot pins that are inserted into pivot pin holes provided in said socket base.

27. The test system of claim 26, wherein said socket base has a plurality of conductive pads within said cavity.

28. The test system of claim 27, wherein said socket base further comprises a plurality of conductive lines.

29. The test system of claim 28, wherein said conductive lines are electrically coupled to an interposer card.

30. The test system of claim 29, wherein said socket base is fastened to said interposer card.

31. The test system of claim 25, wherein said first and second latches are on opposite ends of said socket base.

32. The test system of claim 31, wherein said first and second springs apply a normal force pressure on respective first and second latches such that said first and second latches impinge on a surface of said cavity.

33. A method of using an integrated circuit package testing device, comprising:
inserting an integrated circuit within a cavity of a socket base;
securing said integrated circuit within said cavity with at least one latch, said latch coupled to said socket base by at least one device such that said latch is capable of pivoting about an axis and provides an unobstructed path to a center of said integrated circuit;
exposing said integrated circuit to radiant energy; and
reading out output signals from said integrated circuit.

34. The method of claim 33, further comprising securing said integrated circuit with a second latch, said second latch coupled to said socket base by a second device such that said second latch is capable of pivoting about a second axis.
